(19) United States
(12) Patent Application Publication
(10) Pub. No.: US 2021/0222919 A1
(43) Pub. Date: Jul. 22, 2021

(54) Thermoelectric Cooler, Optical Sub-Assembly, and Optical Module

(71) Applicant: Huawei Technologies Co., Ltd., Shenzhen (CN)

(72) Inventors: Xing Fu, Kyiv (UA); Chengpeng Yang, Dongguan (CN); Ningjun Zhu, Yokohama (JP); Quanming Li, Dongguan (CN)

(21) Appl. No.: 17/224,539

(22) Filed: Apr. 7, 2021

Related U.S. Application Data
(63) Continuation of application No. 15/907,975, filed on Feb. 28, 2018.
Application No. 15/907,975 is a continuation of application No. PCT/CN2016/080458, filed on Apr. 28, 2016.

(30) Foreign Application Priority Data
Aug. 31, 2015 (CN) 201510548768.7

(51) Int. Cl. F25B 21/02; H01L 23/38; H01L 35/04; H01S 5/024; H01S 5/06

(52) U.S. Cl. CPC F25B 21/02; H01L 23/38; H01S 5/0612; H01S 5/02415; H01L 35/04

(57) ABSTRACT

A thermoelectric cooler (TEC) configured to support a heat source device and perform temperature control on the heat source device. The TEC includes a first base plate, a second base plate disposed opposite to the first base plate, and first elements. The first base plate is configured to support the heat source device. An accommodation space is formed between the first base plate and the second base plate. The first elements are arranged at intervals within the accommodation space, and are all connected to the first base plate and the second base plate.

### CROSS-REFERENCE TO RELATED APPLICATIONS

This application is a continuation of U.S. patent application Ser. No. 15/907,975, filed on Feb. 28, 2018, which is a continuation of International Patent Application No. PCT/CN2016/080458, filed on Apr. 28, 2016, which claims priority to Chinese Patent Application No. 201510548768.7, filed on Aug. 31, 2015. All of the afore-mentioned patent applications are hereby incorporated by reference in their entireties.

### TECHNICAL FIELD

The present disclosure relates to the field of communications technologies, and in particular, to a thermoelectric cooler (TEC), an optical sub-assembly, and an optical module.

### BACKGROUND

An optical sub-assembly is an important device in the optical communications field. A chip (in particular, a laser chip) in the optical sub-assembly has high sensitivity to a temperature. To ensure stability of the chip in the optical sub-assembly in sending or receiving signals, generally, a TEC is used to perform accurate temperature control on the laser chip (for example, a temperature of the chip is controlled to be 45±0.1° C.).

As the optical sub-assembly is developed toward a high speed (for example, developed from a 100 gigabit (G) transmitter optical sub-assembly (TOSA) to a 400 G TOSA), power consumption of the laser chip or other electronic parts and components located on a base plate of the TEC increases, and further, heat generated by the laser chip or other electronic parts and components increases, and performance thereof is affected. Therefore, for the heat, an effective heat dissipation solution needs to be provided.

### SUMMARY

An embodiment of the present disclosure provides a TEC to effectively dissipate heat of a heat emitting element in an optical sub-assembly.

The present disclosure further provides an optical sub-assembly and an optical module.

According to a first aspect of the present disclosure, a TEC is provided and configured to support a heat source device and perform temperature control on the heat source device, where the TEC includes a first base plate, a second base plate disposed opposite to the first base plate, and multiple couples of first elements, the first base plate is configured to support the heat source device, an accommodation space is formed between the first base plate and the second base plate, the multiple couples of first elements are arranged at intervals within the accommodation space, the multiple couples of first elements are all connected to the first base plate and the second base plate, the multiple couples of first elements are connected to an external power source to adjust a temperature difference between the first base plate and the second base plate by changing a voltage or a current and implement temperature control on the heat source device, the accommodation space includes a first area and a second area adjacent to the first area, the first area is disposed in a correspondence to the heat source device, and density of first elements in the first area is greater than density of first elements in the second area.

With reference to the first aspect, in first possible implementation, the multiple couples of first elements are all arranged in the first area.

With reference to the first possible implementation, in a possible implementation, the second area is a vacant area; or a support body connected between the first base plate and the second base plate is disposed in the second area.

With reference to the first aspect, in a possible implementation, the first area is connected to the second area, the multiple couples of first elements are arranged in the first area and the second area, and the multiple couples of first elements are arranged in such a manner that density gradually decreases in a direction from the first area to the second area.

With reference to the first aspect, in a possible implementation, the first area is connected to the second area, the multiple couples of first elements are arranged in the first area and the second area, the second area includes a first subarea and a second subarea, and the first subarea and the second subarea are respectively located on two sides of the first area; and the multiple couples of first elements are arranged in such a manner that density gradually decreases in a direction from the first area to the first subarea and in a direction from the first area to the second subarea.

With reference to the first possible implementation, in a possible implementation, the second area includes a first subarea and a second subarea, the first subarea and the second subarea are respectively located on two sides of the first area, and the first subarea and the second subarea are vacant areas; or a support body connected between the first base plate and the second base plate is disposed in at least one subarea of the first subarea or the second subarea.

With reference to the first aspect, in a possible implementation, the support body is made of a non-thermoelectric material.

With reference to the first aspect, in a possible implementation, the TEC further includes one or more couples of second elements, the one or more couples of second elements are arranged in the second area, and when there are multiple couples of second elements, density of second elements in the second area is less than the density of the first elements in the first area.

With reference to the first aspect, in n possible implementation, the second area includes a first subarea and a second subarea, the first subarea and the second subarea are respectively located on two sides of the first area, the TEC further includes one or more couples of second elements, the second elements are disposed in at least one subarea of the first subarea or the second subarea, and when there are multiple couples of second elements, density of second elements in the second area is less than the density of the first elements in the first area.

With reference to the first aspect, in a possible implementation, each couple of first elements includes two element bodies, and the two element bodies are disposed at an interval and are both connected to the first base plate and the second base plate.

With reference to the first aspect, in a possible implementation, the TEC further includes a conductor that is located on the second base plate and is close to the accommodation space, the conductor is electrically connected to one of two element bodies in outermost first elements within the accommodation space, and every two element bodies in the multiple couples of first elements are connected in series.

With reference to the first aspect, in a possible implementation, the TEC further includes a temperature detector and a control circuit, the temperature detector is connected to the heat source device to detect a temperature of the heat source device and transfer the temperature to the control circuit, and the control circuit is configured to control voltage values or current values on the multiple couples of first elements.

With reference to the first aspect, in a possible implementation, the heat source device is located at one end of the first base plate.

With reference to the first aspect, in a possible implementation, the heat source device is located in a position different from ends of the first base plate.

With reference to the first aspect, in a possible implementation, the first base plate and the second base plate are made of an aluminum nitride material, an aluminum oxide material, or a silicon carbide material.

With reference to the first aspect, in a possible implementation, the TEC further includes a passive optical component disposed on the first base plate, and the passive optical component is located on one side opposite to the second area.

According to a second aspect, an optical sub-assembly is provided and includes a base, where the optical sub-assembly further includes the TEC according to any one of the foregoing possible implementations, the TEC is installed on the base, and the second base plate contacts a surface of the base.

According to a third aspect, an optical module is provided and includes a housing, where the optical module further includes the optical sub-assembly according to the second aspect, and the optical sub-assembly is disposed in the housing.

In the present disclosure, density of elements in an area corresponding to a heat source device is greater than density of elements in another area. Therefore, a TEC can dissipate heat of the heat source device on a first base plate in time, and this helps to effectively keep the heat source device on the first base plate at a constant temperature.

### BRIEF DESCRIPTION OF DRAWINGS

To describe the technical solutions in the embodiments of the present disclosure more clearly, the following briefly describes the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a schematic structural diagram of a TEC according to a first embodiment of the present disclosure;

FIG. 2 is a schematic diagram of an optical sub-assembly having the TEC in FIG. 1;

FIG. 3 is a schematic structural diagram of a TEC according to a second embodiment of the present disclosure;

FIG. 4 is a schematic structural diagram of a TEC according to a third embodiment of the present disclosure;

FIG. 5 is a schematic diagram of an optical sub-assembly having the TEC in FIG. 4; and

FIG. 6 is a schematic structural diagram of a TEC according to a fourth embodiment of the present disclosure.

### DESCRIPTION OF EMBODIMENTS

To make the disclosure objectives, features, and advantages of the present disclosure clearer and more comprehensible, the following clearly describes the technical solutions in the embodiments of the present disclosure with reference to the accompanying drawings in the embodiments of the present disclosure. Apparently, the embodiments described in the following are merely some rather than all of the embodiments of the present disclosure. All other embodiments obtained by a person of ordinary skill in the art based on the embodiments of the present disclosure without creative efforts shall fall within the protection scope of the present disclosure.

In the specification, claims, and accompanying drawings of the present disclosure, the terms “first”, “second”, “third”, “fourth”, and so on (if existent) are intended to distinguish between similar objects but do not necessarily indicate a specific order or sequence. It should be understood that the data termed in such a way are interchangeable in proper circumstances so that the embodiments of the present disclosure described herein can be implemented in orders except the order illustrated or described herein. Moreover, the terms “include”, “contain” and any other variants mean to cover the non-exclusive inclusion, for example, a process, method, system, product, or device that includes a list of steps or units is not necessarily limited to those units, but may include other units not expressly listed or inherent to such a process, method, system, product, or device.

The following provides detailed descriptions separately by using specific embodiments.

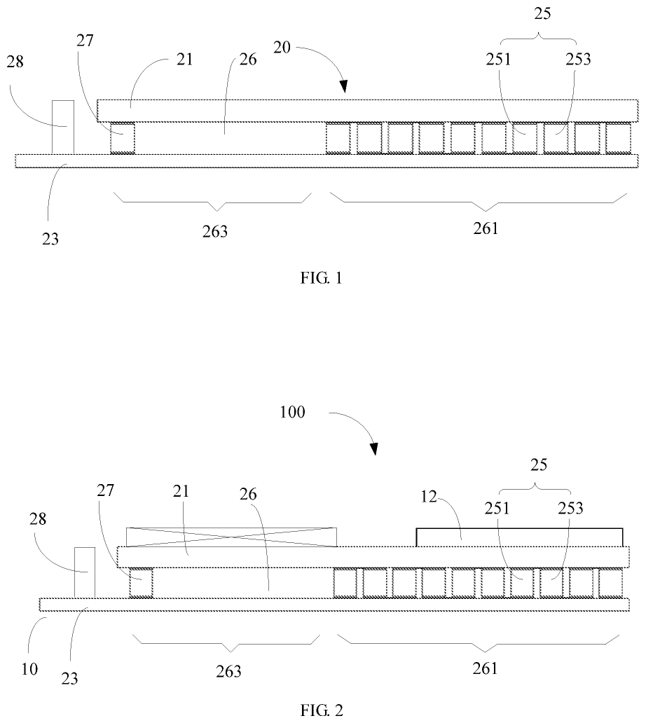

Referring to FIG. 1 and FIG. 2, a first embodiment of the present disclosure provides a TEC 20 and an optical sub-assembly 100 having the TEC 20. The optical sub-assembly 100 includes a base 10 and a heat source device 12. The TEC 20 includes a first base plate 21, a second base plate 23, and multiple couples of first elements 25. The first base plate 21 is configured to support the heat source device 12. An accommodation space 26 is formed between the first base plate 21 and the second base plate 23. The multiple couples of first elements 25 are arranged at intervals within the accommodation space 26, and the multiple couples of first elements 25 are all connected to the first base plate 21 and the second base plate 23. The multiple couples of first elements 25 are connected to an external power source to adjust their cooling or heating effect by receiving a voltage or a current and implement temperature control on the heat source device 12. The accommodation space 26 includes a first area 261 and a second area 263 adjacent to the first area 261. The first area 261 is disposed in a correspondence to the heat source device 12, and density of first elements 25 in the first area 261 is greater than density of first elements 25 in the second area 263. The TEC is installed on the base 10, and is configured to support the heat source device 12 of the optical sub-assembly 100 and perform temperature control on the heat source device 12. The second base plate 23 contacts a surface of the base 10.

Further, the multiple couples of first elements 25 are all arranged in the first area 261. The second area 263 is a vacant area; or a support body connected between the first base plate 21 and the second base plate 23 is disposed in the second area 263.

In a first implementation of this embodiment, preferably, a support body 27 connected between the first base plate 21 and the second base plate 23 is disposed in the second area 263. There are one or more support bodies 27, and a size of the support body 27 is the same as a size of the element. In another implementation, the second area 23 is a vacant area. A support body 27 is disposed in the second area 263, and the support body 27 is made of a non-thermoelectric material. The support body 27 is configured to support the first base plate 21. When there are multiple support bodies 27, they may be arranged regularly in the second area 263.

Still, in a second implementation of this embodiment, the TEC further includes one or more couples of second elements (not marked in the figure). The one or more couples of second elements are arranged in the second area 263. When there are multiple couples of second elements, an arrangement manner in the second area 263 is different from a gradual decrease arrangement manner, for example, the second elements are arranged in a matrix form. In addition, density of second elements in the second area 263 is less than the density of the first elements 25 in the first area 261. The second elements are connected to the external power source.

Specifically, the base 10 is a flat plate, and is configured to support the TEC 20. The TEC 20 is installed on a surface 11 of the base 10. The second base plate 23 contacts the surface 11. Both the first base plate 21 and the second base plate 23 are rectangular plates. The first base plate 21 is disposed in parallel with the second base plate 23. The first base plate 21 is configured to support the heat source device 12 and other electronic components, for example, a laser chip. In this embodiment, the heat source device 12 is a laser chip. The heat source device 12 is disposed on a surface of the first base plate 21 far away from the second base plate 23, and is located above the first area 261. In addition, the heat source device 12 is located at one end of the first base plate 21. In this embodiment, division of the first area 261 and the second area 263 may be determined according to the position occupied by the heat source device 12, so long as it is ensured that the heat source device 12 is located above the first area 261 and disposed opposite to the first area 261.

The multiple couples of first elements 25 are located in the first area 21. Two opposite ends of each first element are respectively connected to the first base plate 21 and the second base plate 23. A direction from left to right within the accommodation space 26 is used as a horizontal direction, and a direction vertical to the horizontal direction is used as a vertical direction. In the horizontal direction, the multiple couples of first elements 25 are in one column, or in multiple columns disposed at intervals. In the vertical direction, the multiple couples of first elements 25 are in one column, or in multiple columns disposed at intervals. In this embodiment, five couples of first elements 25 are disposed compactly at intervals in the horizontal direction.

Further, each couple of first elements 25 includes two element bodies. The two element bodies are an element body 251 and an element body 253 respectively. The element body 251 and the element body 253 are arranged at an interval and are both connected to the first base plate 21 and the second base plate 23; that is, two opposite ends of the element body 251 and the element body 253 are respectively connected to the first base plate 21 and the second base plate 23. In this embodiment, the element body 251 and the element body 253 are arranged and disposed in parallel. In another implementation, the element body 252 and the element body 253 may be arranged in disorder. The element body 251 and the element body 253 include different dopants, so that the element body 251 and the element body 253 have an opposite performance relationship, for example, an electron-hole relationship. In this embodiment, the element body 251 is a P-type element that includes electrons and is formed by a BiTe-type material with a dopant. The element body 253 is an N-type element that includes holes and is formed by a BiTe-type material with a dopant. Therefore, when a current enters the element body 251 from a bottom of the element body 251, and then enters the element body 253 from a top, the element body 251 and the element body 253 transfer heat in a same direction.

Further, the first base plate 21 and the second base plate 23 are made of an aluminum nitride material, an aluminum oxide material, or a silicon carbide material. In this embodiment, the first base plate 21 is made of an aluminum nitride material, and the second base plate 23 is made of an aluminum oxide material.

Further, the TEC 20 further includes a conductor 28 that is located on the second base plate 23 and is close to the accommodation space 26. The conductor 28 is electrically connected to one of two element bodies in outermost first elements within the accommodation space 26, and all element bodies in the multiple couples of first elements 25 are connected in series. Specifically, the conductor 28 is connected to the external power source to supply power to the first elements. The conductor 28 is disposed at one end of the second base plate 23. A conductive metal sheet is disposed between the conductor 28 and the second base plate 23, and configured to electrically connect to the first elements. Specifically, in a first couple of first elements 25 that is within the accommodation space and close to the conductor 28, a first metal sheet is disposed between the element body 251 and the second base plate 23. The conductor and the element body 251 are connected in series by using the first metal sheet. The element body 251 and the element body 253 are connected in series by using a second metal sheet disposed on the first base plate 21. The element body 251 in a second group and the element body 253 in the first group are connected in series by using a third metal sheet disposed on the second base plate 23, and so on. In this way, all elements in the multiple couples of first elements 25 are electrically connected in series. A current transmitted by the conductor 28 to the first element body 25 moves from the second base plate 23 toward the first base plate 21 through the first element body 25, enters the element body 253 through the first metal sheet, and flows back to the second base plate 23. The current makes a waveform motion track. In this process, using cooling of the heat source device 12 as an example, all electrons in the element body 251 and holes in the second element body move from the first base plate 21 to the second base plate 23, and at the same time, transfer heat from the first base plate 21 to the second base plate 23. Finally, heat transfer from the first base plate 21 to the second base plate is implemented, heat on the first base plate 21 is reduced, and temperature stability of the heat source device 12 is improved.

Further, the TEC further includes a temperature detector (not shown in the figure) and a control circuit. The temperature detector is connected to the heat source device 12 to detect a temperature of the heat source device 12 and transfer the temperature to the control circuit. The control circuit is configured to control voltage values or current values on the multiple couples of first elements 25, so that the heat source device 12 keeps a temperature balance, that is, an objective of temperature control in a temperature range is achieved. In this embodiment, the temperature detector is a thermistor.

Further, the TEC further includes a passive optical component disposed on the first base plate 21. The passive optical component is located on one side opposite to the second area 263. The passive optical component is an optical component or the like that does not emit heat itself, but requires an ambient temperature range. When the passive optical component is disposed, a quantity of first elements or second elements in the second area 263 is increased to improve an ambient temperature condition of the passive optical component.

Referring to FIG. 3, in a second embodiment of the present disclosure, a difference from the first embodiment lies in an element arrangement manner. That is, the multiple couples of first elements 25 are arranged in a first area 261 and a second area 263, and the multiple couples of first elements 25 are arranged in such a manner that density gradually decreases in a direction from the first area 261 to the second area 263. In this embodiment, density of elements in the first area 261 is greater, and heat of the heat source device 12 disposed on the first base plate 21 can be better conducted, so that the temperature of the heat source device 12 is within a specified range. In this embodiment, division of the first area 261 and the second area 263 is determined according to an area occupied by the heat source device 12. In addition, a boundary between the first area 261 and the second area 263 may be located between two element bodies in one couple of first elements, or may be located between two couples of elements.

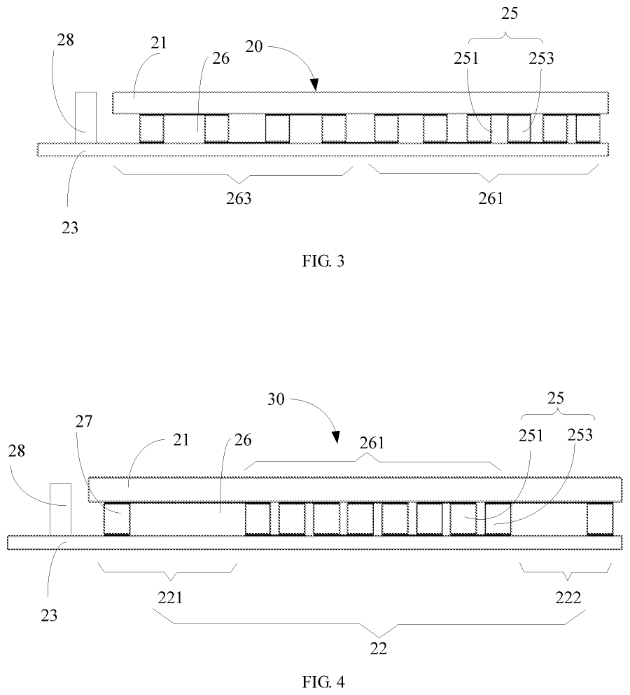

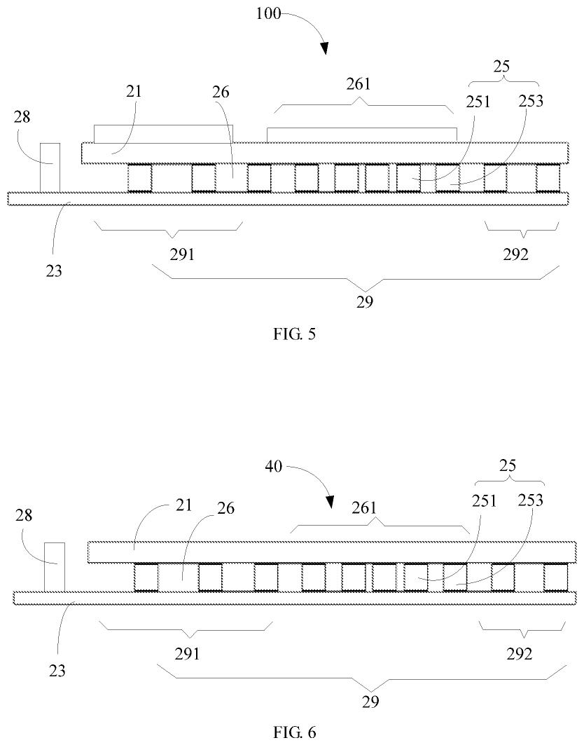

Referring to FIG. 4 and FIG. 5, in a third embodiment of the present disclosure, the multiple couples of elements in the TEC 30 are disposed in the first area 261. The second area 22 includes a first subarea 221 and a second subarea 222. The first subarea 221 and the second subarea 222 are respectively located on two sides of the first area 261, and the first subarea 221 and the second subarea 222 are vacant areas; or a support body 27 connected between the first base plate 21 and the second base plate 23 is disposed in at least one subarea in the first subarea 221 and the second subarea 222. Preferably, the first subarea 221 and the second subarea 222 are vacant areas.

Further, in an implementation of the third embodiment, a support body 27 is disposed in both the first subarea 221 and the second subarea 222. The support body 27 is made of a non-thermoelectric material, and is mainly configured to support the first base plate 21. In another implementation, a support body 27 configured to support the first base plate 21 is disposed in the first subarea 221 or the second subarea 222. In this manner, support bodies 27 may be arranged regularly. It should be noted that, when the support body 27 is made of a non-thermoelectric material, multiple couples of first elements 25 in the first area 261 are all located in the first area 261 in pairs; or the support body 27 is located between two couples of elements, and multiple support bodies 27 are alternately disposed with the multiple couples of elements.

Further, in another implementation of the third embodiment, the TEC further includes one or more couples of second elements (not marked in the figure). The second elements are disposed in at least one subarea in the first subarea 221 and the second subarea 222. The second elements are connected to an external power source. When there are multiple couples of second elements, an arrangement manner in the first subarea 221 or the second subarea 222 is different from a gradual decrease arrangement manner. It should be noted that, when there are second elements, one element in one couple of first elements 25 in adjacent positions of the first area 261 and the second area 22 may be located in the first area 261, and the other one is located in the second area 22, or both are located in the first area. Density of second elements in the second area 22 is less than density of first elements 25 in the first area 261. In this manner, heat dissipation may be performed in a larger area on the first base plate 21, so that the temperature of the heat source device 12 is within a specified range.

Further, the heat source device 12 is located in a position different from ends of the first base plate 21. For example, the heat source device 12 is located in a middle of the first base plate 21 or in a position near a middle. In this embodiment, the heat source device 12 is located in a middle position on the first base plate 21 (as shown in FIG. 5).

Referring to FIG. 6, in a fourth embodiment of the present disclosure, a difference from the third embodiment lies in that the multiple couples of first elements 25 in the TEC 40 are arranged in the first area 261 and the second area 29. The second area 29 includes a first subarea 291 and a second subarea 292. The first subarea 291 and the second subarea 292 are respectively located on two sides of the first area 261. The multiple couples of first elements 25 are arranged in such a manner that density gradually decreases in a direction from the first area 261 to the first subarea 291 and in a direction from the first area 261 to the second subarea 292. Density of elements in the first area 261 is greater, and a part of heat of the heat source device 12 disposed on the first base plate 21 can be better dissipated, so that the temperature of the heat source device 12 is within a specified range.

In the present disclosure, density of element bodies in a position corresponding to the heat source device 12 is increased, so that the TEC 20 dissipates heat of the heat source device 12 on the first base plate in time. In addition, in view of a problem of uneven heat distribution of a heat source in the prior art, element bodies are arranged properly in the present disclosure. This can effectively dissipate heat in a heat source centralization position, enhance a cooling effect of the TEC, and further increase a coefficient of performance (COP) value of the TEC. It is understandable that, the TEC 20 in the present disclosure may also be applicable to an electronic component, for example, a central processing unit (CPU), in addition to an optical sub-assembly.

The present disclosure further provides an optical module. The optical module includes a housing (not shown in the figure) and the optical sub-assembly 100 having the TEC 20 in any one of the foregoing embodiments. The optical sub-assembly 100 is disposed in the housing.

What are disclosed above are merely examples of embodiments of the present disclosure, and certainly are not intended to limit the protection scope of the present disclosure. Any equivalent modification made in accordance with the claims of the present disclosure shall fall within the scope of the present disclosure.

1. A thermoelectric cooler (TEC) comprising:
a first base plate configured to support a heat source device;
a second base plate disposed opposite to the first base plate;
an accommodation space formed between the first base plate and the second base plate, wherein the accommodation space comprises a first area and a second area adjacent to the first area; and
a plurality of first elements arranged at intervals within the accommodation space, connected to the first base plate and the second base plate, and configured to connect to an external power source to adjust a temperature difference between the first base plate and the second base plate by changing a voltage or a current to implement temperature control on the heat source device,
wherein the first area is disposed in a position corresponding to the heat source device, and
wherein a first density of the first elements in the first area is greater than a second density of the first elements in the second area.

2.-3. (canceled)

4. The TEC of claim 1, wherein the first area is connected to the second area, and wherein the first elements are arranged in such a manner that a third density of the first elements gradually decreases in a direction from the first area to the second area.

5. The TEC of claim 4, wherein the second area comprises a first subarea and a second subarea, wherein the first subarea and the second subarea are located on two sides of the first area, and wherein the first elements are arranged in such a manner that a fourth density of the first elements gradually decreases in a direction from the first area to the first subarea and in a direction from the first area to the second subarea.

6. The TEC of claim 1, wherein the second area comprises a first subarea and a second subarea, wherein the first subarea and the second subarea are located on two sides of the first area, and wherein the first subarea and the second subarea are vacant areas.

7. The TEC of claim 1, further comprising one or more couples of second elements arranged in the second area.

8. The TEC of claim 1, wherein the first elements comprise two element bodies disposed at an interval and connected to the first base plate and the second base plate.

9. The TEC of claim 8, further comprising a conductor disposed on the second base plate, wherein the conductor is electrically connected to one of two element bodies in an outermost couple of first elements within the accommodation space, and wherein all element bodies in the first elements are connected in series.

10. The TEC of claim 1, further comprising:
a temperature detector connected to the heat source device and configured to detect a temperature of the heat source device and transfer the temperature to the control circuit; and
a control circuit connected to the first elements and configured to control voltage values on the first elements.

11. The TEC of claim 1, further comprising a passive optical component disposed on one side of the first base plate.

12. The TEC of claim 1, wherein the second area comprises a first subarea and a second subarea, wherein the first subarea and the second subarea are located on two sides of the first area, and wherein a support body is connected to the first base plate and the second base plate and is disposed in at least one of the first subarea or the second subarea.

13. The TEC of claim 1, further comprising a plurality of couples of second elements arranged in the second area, and wherein a fifth density of the second elements in the second area is less than the first density.

14. The TEC of claim 6, wherein the second area comprises a first subarea and a second subarea, wherein the first subarea and the second subarea are located on two sides of the first area, wherein the TEC further comprises a plurality of couples of second elements, wherein the second elements are disposed in at least one of the first subarea or the second subarea, and wherein a sixth density of the second elements in the second area is less than the first density.

15. (canceled)

16. An optical sub-assembly comprising:
a base;
a heat source device; and
a thermoelectric cooler (TEC) installed on the base and comprising:
a first base plate configured to support the heat source device;
a second base plate disposed opposite to the first base plate and contacting a surface of the base;
an accommodation space formed between the first base plate and the second base plate, wherein the accommodation space comprises a first area and a second area adjacent to the first area; and
a plurality of first elements arranged at intervals within the accommodation space, connected to the first base plate and the second base plate, and configured to connect to an external power source to adjust a temperature difference between the first base plate and the second base plate by changing a voltage or a current to implement temperature control on the heat source device,
wherein the first area is disposed in a position corresponding to the heat source device, and
wherein a first density of the first elements in the first area is greater than a second density of the first elements in the second area.

17. An optical system comprising:
a housing; and
an optical sub-assembly disposed in the housing and comprising:
a base;
a heat source device; and
a thermoelectric cooler (TEC) installed on the base and comprising:
a first base plate configured to support the heat source device;
a second base plate disposed opposite to the first base plate and contacting a surface of the base;
an accommodation space formed between the first base plate and the second base plate, wherein the accommodation space comprises a first area and a second area adjacent to the first area; and
a plurality of first elements arranged at intervals within the accommodation space, connected to the first base plate and the second base plate, and configured to connect to an external power source to adjust a temperature difference between the first base plate and the second base plate by changing a voltage or a current to implement temperature control on the heat source device,
wherein the first area is disposed in a position corresponding to the heat source device, and
wherein a first density of the first elements in the first area is greater than a second density of the first elements in the second area.

18. The optical system of claim 17, wherein the TEC further comprises one or more couples of second elements arranged in the second area.

19. The optical system of claim 17, wherein the TEC further comprises a plurality of couples of second elements arranged in the second area, and wherein a third density of the second elements in the second area is less than the first density.

20. The optical system of claim 17, wherein the second area comprises a first subarea and a second subarea, wherein the first subarea and the second subarea are located on two sides of the first area, and wherein the first elements are arranged in such a manner that a fourth density of the first elements gradually decreases in a direction from the first area to the first subarea and in a direction from the first area to the second subarea.

21. The optical sub-assembly of claim 16, wherein the TEC further comprises one or more couples of second elements arranged in the second area.

22. The optical sub-assembly of claim 16, wherein the TEC further comprises a plurality of couples of second elements arranged in the second area, and wherein a third density of the second elements in the second area is less than the first density.

23. The optical sub-assembly of claim 16, wherein the second area comprises a first subarea and a second subarea, wherein the first subarea and the second subarea are located on two sides of the first area, and wherein the first elements are arranged in such a manner that a fourth density of the first elements gradually decreases in a direction from the first area to the first subarea and in a direction from the first area to the second subarea.
